(19) United States
(12) Patent Application Publication
(10) Pub. No.: US 2025/0056971 A1
(43) Pub. Date: Feb. 13, 2025

(54) DISPLAY DEVICE AND METHOD OF MANUFACTURING THE SAME

(71) Applicant: Samsung Display Co., Ltd., Yongin-si (KR)

(72) Inventors: Yoolguk Kim, Yongin-si (KR); Jiyoon Kim, Yongin-si (KR); Sangho Lee, Yongin-si (KR); Heewoon Im, Yongin-si (KR)

(73) Assignee: Samsung Display Co., Ltd., Yongin-si (KR)

(21) Appl. No.: 18/604,494

(22) Filed: Mar. 14, 2024

(30) Foreign Application Priority Data
Aug. 11, 2023 (KR) 10-2023-0105629

(51) Int. Cl. H10K 59/122; H10K 59/12

(52) U.S. Cl. CPC H10K 59/122; H10K 59/1201

(57) ABSTRACT

A display device includes a pixel circuit layer disposed on a substrate and including a pixel circuit, a pixel-defining layer disposed on the pixel circuit layer and including an opening, a first electrode disposed on the pixel circuit layer, disposed in the opening of the pixel-defining layer, and having a portion disposed on a side wall of the pixel-defining layer, a first common layer on the first electrode, an emission layer on the first common layer, a second common layer on the emission layer, and a second electrode on the second common layer, wherein an upper surface of the first common layer is at a higher level than an upper surface of the first electrode.

### CROSS-REFERENCE TO RELATED APPLICATION

This application claims priority to and benefits of Korean Patent Application No. 10-2023-0105629 under 35 U.S.C. § 119, filed on Aug. 11, 2023, in the Korean Intellectual Property Office (KIPO), the disclosure of which is incorporated herein by reference in its entirety.

### BACKGROUND

### 1. Technical Field

One or more embodiments relate to a display device in which lighting quality of a light-emitting element is improved by preventing, in an emission area, residues of a material for forming a pixel-defining layer, and a method of manufacturing the display device.

### 2. Description of the Related Art

Display devices visually display data. With the development of electronic devices, such as mobile phones, personal digital assistants (PDAs), computers, and large televisions (TVs), various types of display devices applicable thereto have been developed. For example, display devices widely used in the market include liquid crystal display devices including a backlight unit and organic light-emitting display devices emitting light of different colors from respective central areas. Also, display devices including a quantum dot color conversion layer (QD-CCL) have recently been developed.

Display devices include light-emitting diodes including a thin-film transistor and an emission layer and operate by emission of light from the light-emitting diodes. The emission layer may be formed in various ways, and for example, may be formed by using an inkjet process.

### SUMMARY

One or more embodiments include a display device with improved lighting quality and a method of manufacturing the display device. However, such a technical problem is an example, and one or more embodiments are not limited thereto.

Additional aspects will be set forth in part in the description which follows and, in part, will be apparent from the description, or may be learned by practice of the presented embodiments of the disclosure.

According to one or more embodiments, a display device includes a pixel circuit layer disposed on a substrate and including a pixel circuit, a pixel-defining layer disposed on the pixel circuit layer and including an opening, a first electrode disposed on the pixel circuit layer, disposed in the opening of the pixel-defining layer, and having a portion disposed on a side wall of the pixel-defining layer, a first common layer on the first electrode, an emission layer on the first common layer, a second common layer on the emission layer, and a second electrode on the second common layer, wherein an upper surface of the first common layer is at a higher level than an upper surface of the first electrode.

The first electrode may include a first portion disposed on the pixel circuit layer and a second portion extending from the first portion and disposed on the side wall of the pixel-defining layer, and the upper surface of the first common layer may be at a higher level than the top of the second portion of the first electrode.

The opening in the pixel-defining layer may include a central area and a peripheral area outside the central area, and the first common layer may be thicker in the central area than in the peripheral area.

The first common layer may have an upper surface that is convex upwards at a central portion of the upper surface.

The opening in the pixel-defining layer may include a central area and a peripheral area outside the central area, and in the central area, the first common layer may be thicker than the emission layer.

The first electrode may be disposed only in the opening of the pixel-defining layer.

The pixel-defining layer may include a first area adjacent to an upper surface of the pixel-defining layer and a second area adjacent to the side wall of the pixel-defining layer, and the pixel-defining layer may have liquid repellency in the first area and the second area.

The pixel-defining layer may include an organic material having a fluoro group (—F) in the first area and the second area.

The first common layer may include a hole injection layer, and the second common layer may include an electron transport layer.

According to one or more embodiments, a display device includes a pixel circuit layer disposed on a substrate and including a pixel circuit, a pixel-defining layer disposed on the pixel circuit layer and including an opening, a first electrode disposed on the pixel circuit layer and disposed in the opening of the pixel-defining layer, a first common layer disposed on the first electrode, an emission layer disposed on the first common layer, a second common layer disposed on the emission layer, and a second electrode disposed on the second common layer, wherein the pixel-defining layer includes a first area adjacent to an upper surface of the pixel-defining layer and a second area adjacent to a side wall of the pixel-defining layer, and the pixel-defining layer has liquid repellency in the first area and the second area.

The second area of the pixel-defining layer may be above the first electrode, wherein the pixel-defining layer may further include a third area adjacent to the side wall of the pixel-defining layer and below the second area and a fourth area in addition to the first to third areas, and a fluorine content of the pixel-defining layer in the first area or the second area may be greater than a fluorine content of the pixel-defining layer in the third area or the fourth area.

An upper surface of the first common layer may be at a higher level than an upper surface of the first electrode.

The opening in the pixel-defining layer may include a central area and a peripheral area outside the central area, and the first common layer may be thicker in the central area than in the peripheral area.

The first electrode may include a first portion disposed on the pixel circuit layer and a second portion extending from the first portion and disposed on the side wall of the pixel-defining layer, and an upper surface of the first common layer may be at a higher level than the top of the second portion of the first electrode.

The first electrode may have a flat upper surface.

The first common layer may be thicker than the emission layer.

The first common layer may be thicker than the second common layer.

In the first area and the second area of the pixel-defining layer, the pixel-defining layer may include an organic material having a fluoro group (—F).

According to one or more embodiments, a method of manufacturing a display device includes forming a pixel circuit layer on a substrate, forming a pixel-defining layer on the pixel circuit layer, the pixel-defining layer including an opening, forming a preliminary first electrode on the pixel circuit layer and the pixel-defining layer, forming a photoresist pattern on the preliminary first electrode, etching the preliminary first electrode by using the photoresist pattern as an etching mask, performing a surface treatment process on the pixel-defining layer such that a surface region of the pixel-defining layer has liquid repellency, removing the photoresist pattern, forming a first common layer, an emission layer, and a second common layer in the opening of the pixel-defining layer, and forming a second electrode on the second common layer.

Due to the surface treatment process, an upper surface and side wall of the pixel-defining layer may have liquid repellency.

The performing of the surface treatment process may include using fluoride-based plasma.

The preliminary first electrode may be etched by a wet etching process.

The emission layer may be formed by an inkjet printing process.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display device according to an embodiment;

FIG. 2 is a schematic diagram of an equivalent circuit of a pixel circuit included in a display device, according to an embodiment;

FIG. 3A is a schematic cross-sectional view of a display device according to an embodiment;

FIG. 3B is a schematic enlarged view of region ‘E’ of FIG. 3A;

FIG. 4A is a schematic cross-sectional view of a display device according to another embodiment;

FIG. 4B is a schematic enlarged view of region ‘F’ of FIG. 4A;

FIGS. 5 to 11 are schematic cross-sectional views of a method of manufacturing a display device, according to an embodiment; and

FIGS. 12 to 15 are schematic cross-sectional views of a method of manufacturing a display device, according to another embodiment.

### DETAILED DESCRIPTION OF THE EMBODIMENTS

Reference will now be made in detail to embodiments, examples of which are illustrated in the accompanying drawings, wherein like reference numerals and/or reference characters refer to like elements throughout. In this regard, the embodiments may have different forms and should not be construed as being limited to the descriptions set forth herein. Accordingly, the embodiments are merely described below, by referring to the figures, to explain aspects of the description.

The term “and/or” includes all combinations of one or more of which associated configurations may define. For example, “A and/or B” may be understood to mean “A, B, or A and B.” For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

As the description allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, the embodiments may have different forms and should not be construed as being limited to the descriptions set forth herein.

One or more embodiments will be described below in more detail with reference to the accompanying drawings. Those elements that are the same or are in correspondence with each other are rendered the same reference numeral regardless of the figure number, and redundant descriptions thereof are omitted.

While such terms as “first” and “second” may be used to describe various elements, such elements must not be limited to the above terms. The above terms are used only to distinguish one element from another.

The singular forms, such as “a” and “an,” as used herein are intended to include the plural forms as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being on another layer, region, or element, it may be directly or indirectly on the other layer, region, or element. That is, for example, intervening layers, regions, or elements may be present.

Sizes of elements in the drawings may be exaggerated or reduced for convenience of explanation. For example, since sizes and thicknesses of elements in the drawings are arbitrarily illustrated for convenience of explanation, the following embodiments are not limited thereto.

When an embodiment may be implemented differently, a certain process order may be performed differently from the described order. For example, two consecutively described processes may be performed substantially at the same time or performed in an order opposite to the described order.

It will be further understood that, when layers, regions, or elements are referred to as being connected to each other, they may be directly connected to each other or may be indirectly connected to each other with intervening layers, regions, or elements therebetween. For example, when layers, regions, or elements are referred to as being electrically connected to each other, they may be directly electrically connected to each other or may be indirectly electrically connected to each other with intervening layers, regions, or elements therebetween.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

A display device may be a device that displays an image, and may be a portable mobile device such as a game console, a multimedia device, or an ultra-small personal computer (PC). The display device described below may include a liquid crystal display device, an electrophoretic display device, an organic light-emitting display device, an inorganic light-emitting display device, a field emission display device, a surface-conduction electron-emitter display device, a quantum dot display device, a plasma display device, and a cathode ray display device. As a display device according to an embodiment, an organic light-emitting display device is described below as an example. However, embodiments described herein may include various types of display devices as described above.

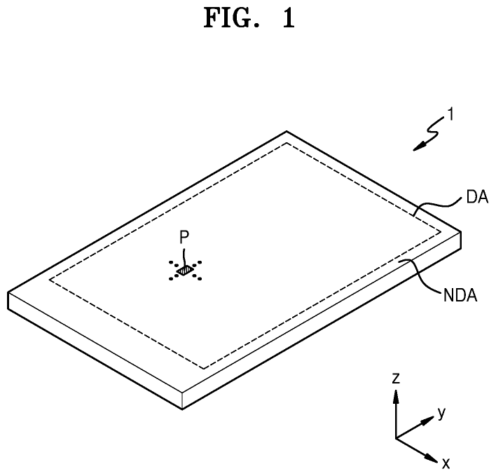

FIG. 1 is a schematic perspective view of a display device 1 according to an embodiment.

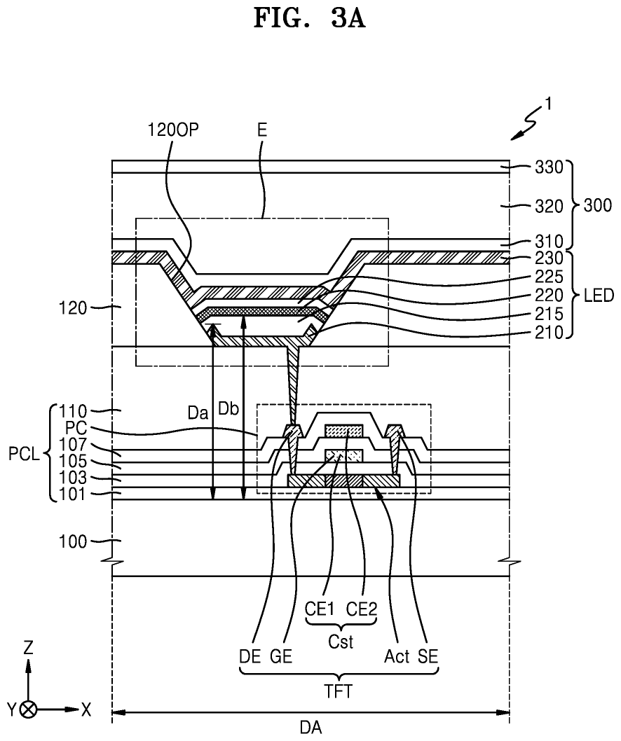

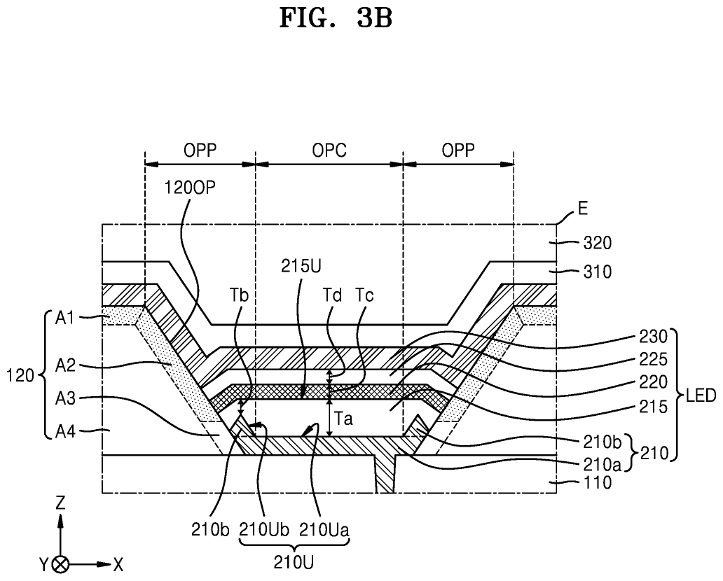

Referring to FIG. 1, the display device 1 may include a display area DA in which pixels P are disposed, and a non-display area NDA outside the display area DA or adjacent thereto. In an embodiment, the non-display area NDA may entirely surround the display area DA. It may be construed as meaning that a substrate 100 (refer to FIG. 3A) included in a display device 1 has the display area DA and the non-display area NDA.

Each pixel P of the display device 1 may be an area capable of emitting light of a certain color, and the display device 1 may provide an image by using light emitted from the pixels P. For example, each pixel P may emit red light, green light, or blue light.

As shown in FIG. 1, the display area DA may have a polygonal shape including a quadrilateral shape. For example, the display area DA may have a rectangular shape having a horizontal length greater than a vertical length, a rectangular shape having a horizontal length less than a vertical length, or a square shape. As another example, the display area DA may have various shapes, such as an oval shape or a circular shape.

The non-display area NDA may be an area in which pixels P are not disposed. A driver for providing an electrical signal or power to pixels P may be disposed in the non-display area NDA. Pads (not shown) to which various electronic devices or printed circuit boards may be electrically connected may be disposed in the non-display area NDA. Each pad may be apart from one another in the non-display area NDA and may be electrically connected to a printed circuit board or an integrated circuit device.

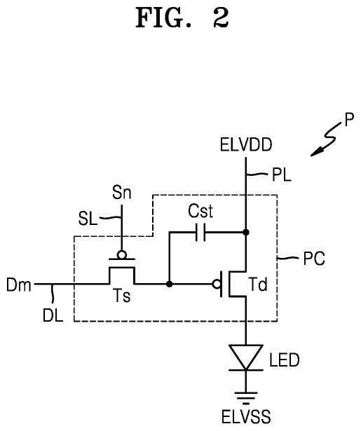

FIG. 2 is a schematic diagram of an equivalent circuit of a pixel circuit PC included in the display device 1, according to an embodiment. The pixel circuit PC may be electrically connected to a light-emitting diode LED, and one light-emitting diode LED may correspond to one pixel P.

The pixel circuit PC may include a first transistor Td, a second transistor Ts, and a storage capacitor Cst.

The second transistor Ts, which is a switching transistor, may be electrically connected to a scan line SL and a data line DL and may be turned on by a switching signal Sn input from the scan line SL to transmit a data signal Dm input from the data line DL to the first transistor Td. The storage capacitor Cst may have an end electrically connected to the second transistor Ts and another end electrically connected to a driving voltage line PL and may store a voltage corresponding to a difference between a voltage received from the second transistor Ts and a driving power voltage ELVDD supplied to the driving voltage line PL.

The first transistor Td, which is a driving transistor, may be electrically connected to the driving voltage line PL and the storage capacitor Cst, and may be configured to control the volume of a driving current flowing from the driving voltage line PL to the light-emitting diode LED, in response to a voltage value stored in the storage capacitor Cst. The light-emitting diode LED may emit light having certain brightness according to the driving current. An opposite electrode of the light-emitting diode LED may receive an electrode power voltage ELVSS.

Although FIG. 2 illustrates a case in which the pixel circuit PC includes two thin-film transistors and one storage capacitor, one or more embodiments are not limited thereto. In another embodiment, the pixel circuit PC may include seven thin-film transistors and one storage capacitor. In another embodiment, the pixel circuit PC may include two or more storage capacitors.

FIG. 3A is a schematic cross-sectional view of the display device 1 according to an embodiment. FIG. 3A is a schematic cross-sectional view in the display area DA of the display device 1. FIG. 3B is a schematic enlarged view of region ‘E’ of FIG. 3A.

Referring to FIGS. 3A and 3B, the display device 1 may include the light-emitting diode LED in the display area DA. The light-emitting diode LED may be electrically connected to the pixel circuit PC disposed between the substrate 100 and the light-emitting diode LED in a direction (e.g., a direction z) perpendicular to the substrate 100.

The display device 1 may include the substrate 100, a pixel circuit layer PCL on the substrate 100, a pixel-defining layer 120 on the pixel circuit layer PCL, the light-emitting diode LED on the pixel circuit layer PCL, and an encapsulation layer 300 on the light-emitting diode LED.

The substrate 100 may include, e.g., glass and/or polymer resin. Examples of the polymer resin may include polyethersulfone (PES), polyarylate (PAR), polyetherimide (PEI), polyethylene naphthalate (PEN), polyethylene terephthalate (PET), polyphenylene sulfide (PPS), polyacrylate, polyimide (PI), polycarbonate (PC), and/or cellulose acetate propionate (CAP). The substrate 100 including polymer resin may be flexible, rollable, or bendable. The substrate 100 may have a multi-layer structure including a layer including the above polymer resin and an inorganic layer (not shown).

The pixel circuit layer PCL may include a buffer layer 101, a first insulating layer 103, a second insulating layer 105, a third insulating layer 107, a thin-film transistor TFT, and/or an organic insulating layer 110.

The buffer layer 101 may be disposed on the substrate 100 to planarize an upper surface of the substrate 100 and block impurities from flowing in from the substrate 100. The buffer layer 101 may include an inorganic insulating material such as silicon oxide (SiOₓ), silicon nitride (SiNₓ), or silicon oxynitride (SiOₓN_{y}). The buffer layer 101 may include a single-layer or multi-layer structure including the above inorganic insulating material.

The pixel circuit PC may include at least one thin-film transistor TFT and the storage capacitor Cst. The thin-film transistor TFT may include a semiconductor layer Act, a gate electrode GE, a source electrode SE, and a drain electrode DE.

The semiconductor layer Act may be disposed on the buffer layer 101. The semiconductor layer Act may include an oxide semiconductor and/or a silicon semiconductor. In case that the semiconductor layer Act includes an oxide semiconductor, the semiconductor layer Act may include, for example, oxide of at least one material selected from the group including indium (In), gallium (Ga), tin (Sn), zirconium (Zr), vanadium (V), hafnium (Hf), cadmium (Cd), germanium (Ge), chromium (Cr), titanium (Ti), and zinc (Zn). For example, the semiconductor layer Act may be an InSnZnO (ITZO) semiconductor layer, an InGaZnO (IGZO) semiconductor layer, or the like. In case that the semiconductor layer Act includes a silicon semiconductor, the semiconductor layer Act may include, for example, amorphous silicon or low-temperature polycrystalline silicon (LTPS).

The gate electrode GE may be disposed over the semiconductor layer Act with the first insulating layer 103 therebetween. The gate electrode GE may overlap a channel region of the semiconductor layer Act. The gate electrode GE may include a low-resistance metal material. For example, the gate electrode GE may have a single-layer or multi-layer structure including one or more metals selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The gate electrode GE may be electrically connected to a gate line configured to apply an electrical signal to the gate electrode GE.

The first insulating layer 103 may be disposed on the buffer layer 101. The first insulating layer 103 may be disposed between the semiconductor layer Act and the gate electrode GE. The first insulating layer 103 may include, for example, an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

The second insulating layer 105 may be disposed on the first insulating layer 103. The second insulating layer 105 may cover the gate electrode GE. In a similar way to the first insulating layer 103, the second insulating layer 105 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

An upper electrode CE2 of the storage capacitor Cst may be disposed on the second insulating layer 105. In an embodiment, the upper electrode CE2 may overlap the gate electrode GE. In this regard, the gate electrode GE and the upper electrode CE2 overlapping each other with the second insulating layer 105 therebetween may constitute the storage capacitor Cst. For example, the gate electrode GE may serve as a lower electrode CE1 of the storage capacitor Cst. As described above, the storage capacitor Cst and the thin-film transistor TFT may overlap each other. In another embodiment, the storage capacitor Cst and the thin-film transistor TFT may not overlap each other.

The third insulating layer 107 may be disposed on the second insulating layer 105. The third insulating layer 107 may cover the upper electrode CE2. The third insulating layer 107 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). The third insulating layer 107 may have a single-layer or multi-layer structure including the above inorganic insulating material.

The source electrode SE and the drain electrode DE may each be disposed on the third insulating layer 107. The source electrode SE and the drain electrode DE may be electrically connected to the semiconductor layer Act through contact holes in the first insulating layer 103, the second insulating layer 105, and the third insulating layer 107. The source electrode SE and the drain electrode DE may include a highly conductive material. At least one of the source electrode SE and the drain electrode DE may include a conductive material including molybdenum (Mo), aluminum (Al), copper (Cu), or titanium (Ti), and may have a multi-layer or single-layer structure including the above material. In an embodiment, at least one of the source electrode SE and the drain electrode DE may have a multi-layer structure of Ti/Al/Ti.

The organic insulating layer 110 may be disposed on the third insulating layer 107. The organic insulating layer 110 may be disposed on the source electrode SE and the drain electrode DE. The organic insulating layer 110 is shown as a single layer, but is not limited thereto, and may have a multi-layer structure.

The organic insulating layer 110 may include an organic material. The organic insulating layer 110 may include an organic insulating material such as a general commercial polymer, for example, polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or a blend thereof. The organic insulating layer 110 may planarize an upper surface of the pixel circuit PC to planarize a surface on which the light-emitting diode LED is to be positioned.

The pixel-defining layer 120 may be disposed on the pixel circuit layer PCL. The pixel-defining layer 120 may be disposed on the organic insulating layer 110. The pixel-defining layer 120 may have an opening 120OP. As shown in FIG. 3B, the opening 120OP in the pixel-defining layer 120 may have a central area OPC in a central portion of the opening 120OP and a peripheral area OPP outside the central area OPC.

The opening 120OP in the pixel-defining layer 120 may expose an entire first electrode 210. For example, the pixel-defining layer 120 may not cover an upper surface of the first electrode 210. An emission layer 220 described below may be in the opening 120OP of the pixel-defining layer 120. In an embodiment, a first common layer 215 and a second common layer 225 described below may be in the opening 120OP of the pixel-defining layer 120. A second electrode 230 described below may be disposed over the emission layer 220. A stacked structure of the first electrode 210, the first common layer 215, the emission layer 220, the second common layer 225, and the second electrode 230 may constitute one light-emitting diode LED. An opening 120OP in the pixel-defining layer 120 may correspond to a light-emitting diode LED and may define an emission area. An area exposed by the opening 120OP in the pixel-defining layer 120 may be defined as an emission area.

The pixel-defining layer 120 may include a first area A1 adjacent to an upper surface of the pixel-defining layer 120, a second area A2 and a third area A3 adjacent to a side wall of the pixel-defining layer 120, and a fourth area A4, which is the remaining area excluding the first to third areas A1, A2, and A3. The second area A2 of the pixel-defining layer 120 may be an area that does not overlap the first electrode 210 in a direction x and/or a direction y. The second area A2 of the pixel-defining layer 120 may be an area above the first electrode 210. In other words, the second area A2 of the pixel-defining layer 120 may be an area at a higher level than the first electrode 210. The third area A3 of the pixel-defining layer 120 may be an area that overlaps the first electrode 210 in the direction x and/or the direction y. The third area A3 of the pixel-defining layer 120 may be an area below the second area A2. The first to third areas A1, A2, and A3 of the pixel-defining layer 120 may be areas adjacent to a surface of the pixel-defining layer 120 and may be referred to as a surface region. The fourth area A4 of the pixel-defining layer 120 is an area disposed in a core portion of the pixel-defining layer 120 and may be referred to as a core region.

In an embodiment, the pixel-defining layer 120 may include an organic insulating material such as polyimide, polyacrylic, or hexamethyldisiloxane (HMDSO). In an embodiment, at least a portion of the pixel-defining layer 120 may have liquid repellency. For example, a surface region of the pixel-defining layer 120 may have liquid repellency. For example, the pixel-defining layer 120 may have liquid repellency in the first area A1 and the second area A2. In the description, having liquid repellency may mean that, during an inkjet process, a contact angle with respect to a solvent constituting an ink including a light-emitting material for forming the emission layer 220 or the ink including a light-emitting material is relatively large. For example, having liquid repellency may mean that, during an inkjet process, a contact angle with respect to a solvent constituting an ink including a light-emitting material for forming the emission layer 220 or the ink including a light-emitting material is about 90 degrees or greater.

In an embodiment, the pixel-defining layer 120 may include a fluorine-based component. For example, the pixel-defining layer 120 may include an organic material having a fluoro group (—F) or a fluorine compound. For example, the pixel-defining layer 120 may include an organic material having a fluoro group (—F) or a fluorine compound in the first area A1 and the second area A2. For example, a fluorine content of the pixel-defining layer 120 in the first area A1 and the second area A2 may be greater than a fluorine content of the pixel-defining layer 120 in the third area A3 and the fourth area A4. The fluoro group or fluorine included in the pixel-defining layer 120 may improve the liquid repellency of the surface of the pixel-defining layer 120.

The light-emitting diode LED may be disposed on the pixel circuit layer PCL. The light-emitting diode LED may be disposed on the organic insulating layer 110. The light-emitting diode LED, for example, may emit red, green, or blue light, or may emit red, green, blue, or white light.

The light-emitting diode LED may be an organic light-emitting diode including an organic emission layer. As another example, the light-emitting diode LED may be an inorganic light-emitting diode including an inorganic emission layer. The light-emitting diode LED may have a micro-scale or nano-scale size. For example, the light-emitting diode LED may be a micro light-emitting diode. As another example, the light-emitting diode LED may be a nanorod light-emitting diode. The nanorod light-emitting diode may include gallium nitride (GaN). In an embodiment, a color conversion layer may be disposed on the nanorod light-emitting diode. The color conversion layer may include quantum dots. As another example, the light-emitting diode LED may be a quantum dot light-emitting diode including a quantum dot emission layer.

The light-emitting diode LED may include the first electrode 210, the first common layer 215, the emission layer 220, the second common layer 225, and the second electrode 230. The first electrode 210 of the light-emitting diode LED may be an anode and the second electrode 230 may be a cathode, but one or more embodiments are not limited thereto. For example, the light-emitting diode LED may be an inverted light-emitting diode in which the first electrode 210 is a cathode and the second electrode 230 is an anode. For convenience of description, the descriptions given below may be based on the light-emitting diode LED in which the first electrode 210 is an anode and the second electrode 230 is a cathode.

The first electrode 210 may be disposed on the organic insulating layer 110. The entire first electrode 210 may be exposed by the opening 120OP in the pixel-defining layer 120. The first electrode 210 may be disposed only in the opening 120OP of the pixel-defining layer 120. In an embodiment, the first electrode 210 may be disposed on the organic insulating layer 110, and a portion of the first electrode 210 may be disposed on the side wall of the pixel-defining layer 120.

The first electrode 210 may be electrically connected to the thin-film transistor TFT. For example, the first electrode 210 may be electrically connected to the thin-film transistor TFT through a contact hole in the organic insulating layer 110.

As shown in FIG. 3B, the first electrode 210 may include a first portion 210a disposed on the pixel circuit layer PCL (of FIG. 3A) and a second portion 210b extending from the first portion 210a and disposed on the side wall of the pixel-defining layer 120. The first portion 210a of the first electrode 210 may be disposed on an upper surface of the organic insulating layer 110. The first portion 210a of the first electrode 210 may be a portion that has an upper surface substantially parallel to the upper surface of the substrate 100. The second portion 210b of the first electrode 210 may protrude from the first portion 210a of the first electrode 210. For example, the second portion 210b of the first electrode 210 may be referred to as a protrusion of the first electrode 210. A central portion of the first portion 210a of the first electrode 210 may be in the central area OPC, and the second portion 210b of the first electrode 210 may be in the peripheral area OPP.

In an embodiment, the upper surface of the first electrode 210 may not be flat. The upper surface of the first electrode 210 may include a first upper surface portion 210Ua in the central area OPC and a second upper surface portion 210Ub in the peripheral area OPP. The first upper surface portion 210Ua may be an upper surface of the first portion 210a of the first electrode 210, and the second upper surface portion 210Ub may be an upper surface of the second portion 210b of the first electrode 210. In an embodiment, the first upper surface portion 210Ua of the first electrode 210 may be substantially parallel to the upper surface of the substrate 100. The second upper surface portion 210Ub of the first electrode 210 may be inclined from the first upper surface portion 210Ua.

The first electrode 210 may include, for example, conductive oxide, such as indium tin oxide (ITO), indium zinc oxide (IZO), zinc oxide (ZnO), indium oxide (In₂O₃), indium gallium oxide (IGO), or aluminum zinc oxide (AZO). The first electrode 210 may include, for example, a reflective layer including silver (Ag), magnesium (Mg), aluminum (Al), platinum (Pt), palladium (Pd), gold (Au), nickel (Ni), neodymium (Nd), iridium (Ir), chromium (Cr), copper (Cu), or a compound thereof. For example, the first electrode 210 may have a double-layer or triple-layer structure including the above reflective layer and at least one conductive oxide layer. In another embodiment, the first electrode 210 may exclude (or not include) silver (Ag) and may include an aluminum (Al)-based compound or a copper (Cu)-based reflective layer.

The first common layer 215 may be disposed in the opening 120OP of the pixel-defining layer 120. The first common layer 215 may be disposed on the first electrode 210. The first common layer 215 may be disposed between the first electrode 210 and the emission layer 220. In an embodiment, the first common layer 215 may be disposed only in the opening 120OP of the pixel-defining layer 120. In other words, the first common layer 215 may be disposed in an island shape. In another embodiment, similar to the second electrode 230, the first common layer 215 may be shared by light-emitting diodes LED. The first common layer 215 is shown as a single layer in FIGS. 3A and 3B, but is not limited thereto. The first common layer 215 may include a hole transport layer (HTL) and/or a hole injection layer (HIL). The first common layer 215 may further include other functional layers in addition to the HTL and the HIL. The first common layer 215 may be formed by an inkjet process.

An upper surface 215U of the first common layer 215 may be at a higher level than an upper surface 210U of the first electrode 210. The upper surface 215U of the first common layer 215 may be at a higher level than the first upper surface portion 210Ua of the first electrode 210 and the second upper surface portion 210Ub of the first electrode 210. An upper surface of the first common layer 215 may be at a higher level than the top of the first electrode 210. As shown in FIG. 3A, a distance Db between the upper surface of the substrate 100 and the upper surface of the first common layer 215 may be greater than a distance Da between the upper surface of the substrate 100 and an uppermost end of the first electrode 210. The upper surface of the first common layer 215 may be at a higher level than the top of the second portion 210b of the first electrode 210. For example, the entire upper surface of the first common layer 215 may be at a higher level than the first electrode 210.

In the description, ‘A is at a higher level than B’ may be defined as A being disposed higher than B in a direction (e.g., the direction z) perpendicular to the upper surface of the substrate 100 based on the substrate 100. For example, ‘A is at a higher level than B’ may be defined as a distance between the upper surface of the substrate 100 and A being greater than a distance between the upper surface of the substrate 100 and B.

Because the upper surface 215U of the first common layer 215 may be higher than the uppermost end of the first electrode 210, a short circuit between the first electrode 210 and the second electrode 230 may be prevented. Accordingly, electrical reliability of the display device 1 may be improved because the upper surface 215U of the first common layer 215 may be higher than the uppermost end of the first electrode 210.

In an embodiment, the first common layer 215 may have an upper surface that is convex upwards at a central portion thereof. For example, at least a portion of the upper surface 215U of the first common layer 215 in the peripheral area OPP may be at a lower level than the upper surface 215U of the first common layer 215 in the central area OPC. A thickness Ta of the first common layer 215 in the central area OPC may be greater than a thickness Tb of the first common layer 215 in the peripheral area OPP. In this regard, a thickness of the first common layer 215 in each of the central area OPC and the peripheral area OPP may be defined as an average thickness in each area. Because the side wall of the pixel-defining layer 120 may exhibit liquid repellency, the upper surface 215U of the first common layer 215 may be lower in height in an area adjacent to the side wall of the pixel-defining layer 120 than in the central area OPC of the opening 120OP of the pixel-defining layer 120.

The emission layer 220 may be disposed in the opening 120OP of the pixel-defining layer 120. The emission layer 220 may be disposed on the first common layer 215. The emission layer 220 may be, for example, an organic emission layer. The organic emission layer may include an organic material including a fluorescent or phosphorescent material that emits red, green, blue, or white light. The organic emission layer may include a low-molecular weight organic material or a polymer organic material. The emission layer 220 may be disposed only in the opening 120OP of the pixel-defining layer 120. For example, the emission layer 220 may be disposed in an island shape. The emission layer 220 may be formed by an inkjet process.

In an embodiment, the emission layer 220 may have an upper surface that is convex at a central portion thereof. For example, at least a portion of the upper surface of the emission layer 220 in the peripheral area OPP may be at a lower level than the upper surface of the emission layer 220 in the central area OPC. Because the side wall of the pixel-defining layer 120 may exhibit liquid repellency, the upper surface of the emission layer 220 may be lower in height in an area adjacent to the side wall of the pixel-defining layer 120 than in the central area OPC of the opening 120OP.

The second common layer 225 may be disposed in the opening 120OP of the pixel-defining layer 120. The second common layer 225 may be disposed on the emission layer 220. The second common layer 225 may be disposed between the second electrode 230 and the emission layer 220. In an embodiment, the second common layer 225 may be disposed only in the opening 120OP of the pixel-defining layer 120. In other words, the second common layer 225 may be disposed in an island shape. In another embodiment, similar to the second electrode 230, the second common layer 225 may be shared by light-emitting diodes LED. The second common layer 225 is shown as a single layer in FIGS. 3A and 3B, but is not limited thereto. The second common layer 225 may include an electron transport layer (ETL) and/or an electron injection layer (EIL). The second common layer 225 may further include other functional layers in addition to the ETL and the EIL. The second common layer 225 may be formed by an inkjet process.

In an embodiment, the second common layer 225 may have an upper surface that is convex at a central portion thereof. For example, at least a portion of the upper surface of the second common layer 225 in the peripheral area OPP may be at a lower level than the upper surface of the second common layer 225 in the central area OPC. Because the side wall of the pixel-defining layer 120 may exhibit liquid repellency, the upper surface of the second common layer 225 may be lower in height in an area adjacent to the side wall of the pixel-defining layer 120 than in the central area OPC of the opening 120OP of the pixel-defining layer 120.

In the central area OPC, the thickness Ta of the first common layer 215 may be greater than a thickness Tc of the emission layer 220. In the central area OPC, the thickness Ta of the first common layer 215 may be greater than a thickness Td of the second common layer 225.

The second electrode 230 may be disposed on the second common layer 225. The second electrode 230 may entirely cover the substrate 100 of the display area DA. The second electrode 230 may be a light-transmitting electrode or a reflective electrode. The second electrode 230 may include a conductive material having a low work function. For example, the second electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. As another example, the second electrode 230 may further include a layer, such as ITO, IZO, ZnO, or In₂O₃, on a (semi) transparent layer including the above material.

The encapsulation layer 300 may be disposed on the light-emitting diode LED. The light-emitting diode LED may be covered by the encapsulation layer 300 and prevented from being damaged due to external moisture or oxygen. The encapsulation layer 300 may cover the display area DA and may extend out of the display area DA. The encapsulation layer 300 may include at least one inorganic encapsulation layer and at least one organic encapsulation layer. For example, the encapsulation layer 300 may include a first inorganic encapsulation layer 310, an organic encapsulation layer 320, and/or a second inorganic encapsulation layer 330.

Because the first inorganic encapsulation layer 310 may be formed along a structure beneath, an upper surface thereof may not be flat. The organic encapsulation layer 320 may cover the first inorganic encapsulation layer 310, and unlike the first inorganic encapsulation layer 310, may have a substantially flat upper surface.

The first inorganic encapsulation layer 310 and the second inorganic encapsulation layer 330 may include one or more inorganic materials, e.g., among aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include acryl-based resin, epoxy-based resin, polyimide, and polyethylene. In an embodiment, the organic encapsulation layer 320 may include acrylate. The organic encapsulation layer 320 may be formed by curing a monomer or applying a polymer.

In some embodiments, other layers, such as a capping layer, may be disposed between the first inorganic encapsulation layer 310 and the second electrode 230.

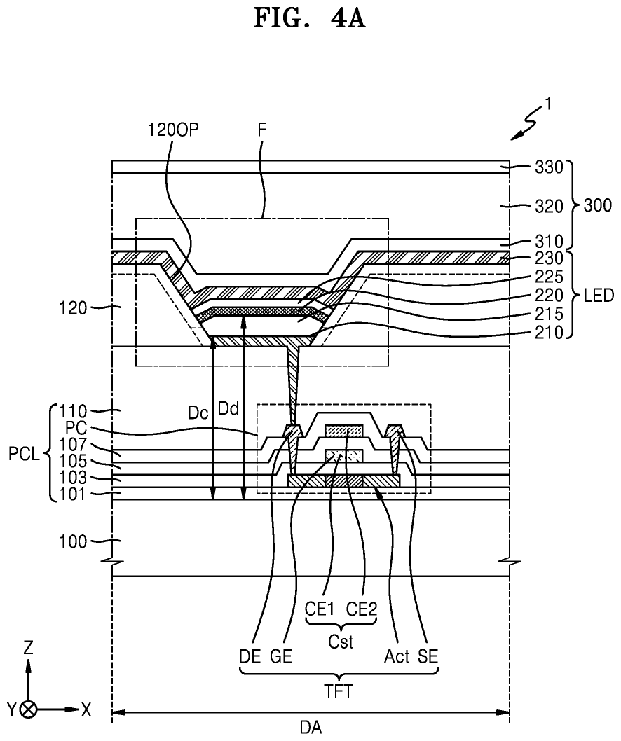

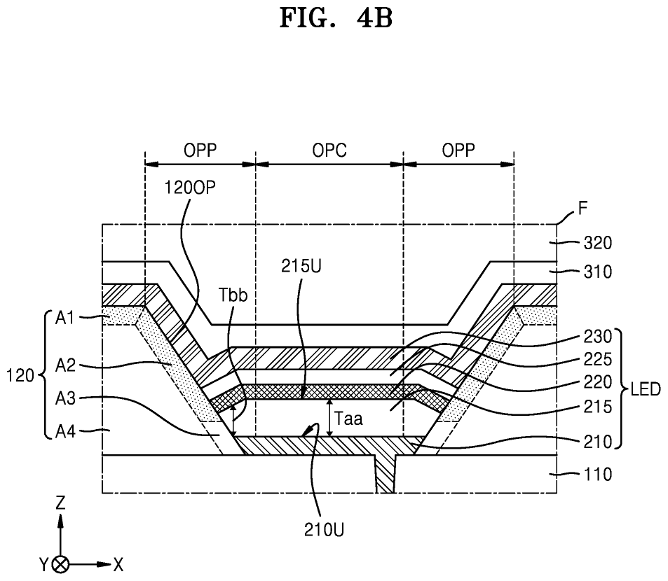

FIG. 4A is a schematic cross-sectional view of the display device 1 according to another embodiment. FIG. 4B is a schematic enlarged view of a region ‘F’ of FIG. 4A. FIGS. 4A and 4B illustrate a modified embodiment of the embodiment described with reference to FIGS. 3A and 3B. A redundant description of the embodiment of FIGS. 3A and 3B may be omitted, and changes therein may be described.

Referring to FIGS. 4A and 4B, the first electrode 210 in the opening 120OP of the pixel-defining layer 120 may be disposed on the organic insulating layer 110. In an embodiment, the upper surface 210U of the first electrode 210 may be substantially flat. The upper surface 210U of the first electrode 210 over the organic insulating layer 110 may be substantially parallel to an upper surface of the substrate 100. In the embodiment, the first electrode 210 may not include a protrusion.

The upper surface 215U of the first common layer 215 may be at a higher level than the upper surface 210U of the first electrode 210. As shown in FIG. 4A, a distance Dd between the upper surface of the substrate 100 and the upper surface 215U of the first common layer 215 may be greater than a distance Dc between the upper surface of the substrate 100 and the upper surface 210U of the first electrode 210.

In an embodiment, the first common layer 215 may have an upper surface that is convex upwards at a central portion thereof. For example, at least a portion of the upper surface 215U of the first common layer 215 in the peripheral area OPP may be at a lower level than the upper surface 215U of the first common layer 215 in the central area OPC. A thickness Taa of the first common layer 215 in the central area OPC may be greater than a thickness Tbb of the first common layer 215 in the peripheral area OPP. In this regard, a thickness of the first common layer 215 in each of the central area OPC and the peripheral area OPP may be defined as an average thickness in each area.

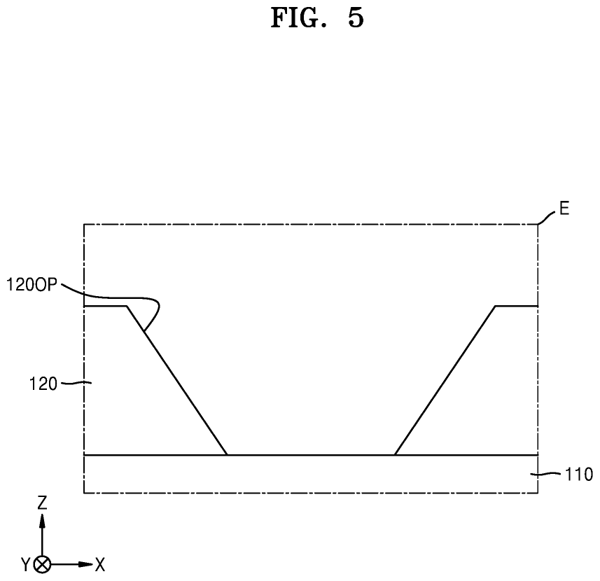

FIGS. 5 to 11 are schematic cross-sectional views of a method of manufacturing a display device, according to an embodiment. FIGS. 5 to 11 illustrate a manufacturing method for forming the embodiment described with reference to FIGS. 3A and 3B. FIGS. 5 to 11 illustrate a manufacturing method in the region corresponding to FIG. 3B.

First, referring to FIG. 3A, the substrate 100 and the pixel circuit layer PCL on the substrate 100 and including the pixel circuit PC may be formed. For example, the buffer layer 101, the semiconductor layer Act, the first insulating layer 103, the gate electrode GE, the second insulating layer 105, the upper electrode CE2, the third insulating layer 107, the source and drain electrodes SE and DE, and/or the organic insulating layer 110 may be sequentially formed on the substrate 100.

Referring to FIG. 5, the pixel-defining layer 120 including the opening 120OP may be formed on the organic insulating layer 110 of the pixel circuit layer PCL (refer to FIG. 3A). The pixel-defining layer 120 may include an organic insulating material such as polyimide, polyacrylic, or hexamethyldisiloxane (HMDSO).

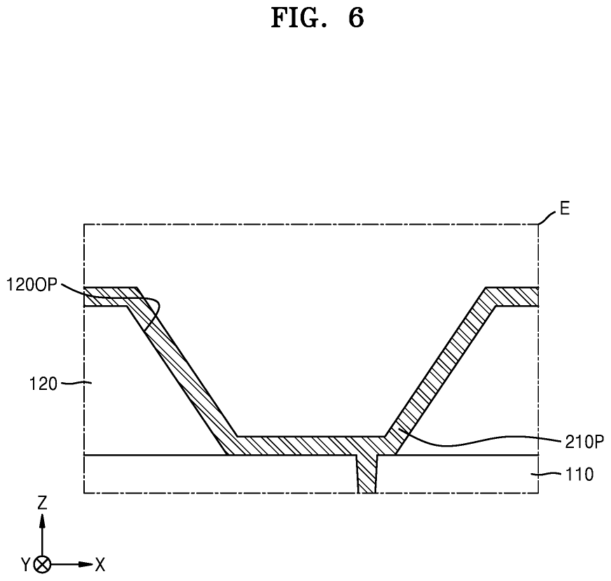

Referring to FIG. 6, a preliminary first electrode 210P may be formed on the organic insulating layer 110 and the pixel-defining layer 120. The preliminary first electrode 210P may be formed, for example, by a sputtering process.

The preliminary first electrode 210P may include, for example, a reflective layer including silver (Ag), magnesium (Mg), aluminum (Al), platinum (Pt), palladium (Pd), gold (Au), nickel (Ni), neodymium (Nd), iridium (Ir), chromium (Cr), copper (Cu), or a compound thereof. The preliminary first electrode 210P may include, for example, a conductive oxide layer, such as indium tin oxide (ITO), indium zinc oxide (IZO), zinc oxide (ZnO), indium oxide (In₂O₃), indium gallium oxide (IGO), or aluminum zinc oxide (AZO). For example, the preliminary first electrode 210P may have a double-layer or triple-layer structure including the above reflective layer and at least one conductive oxide layer.

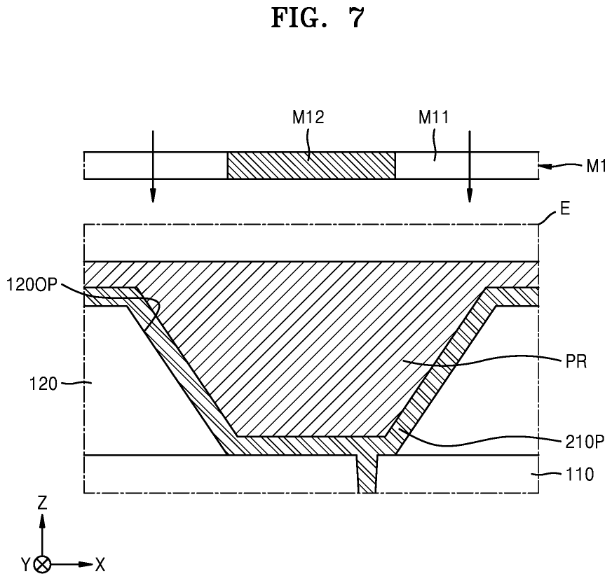

Referring to FIG. 7, a photoresist PR may be formed over the pixel-defining layer 120 and the organic insulating layer 110. The photoresist PR may be a positive or negative photoresist. In the embodiment, a positive photoresist is described as an example for convenience of description. Through a photomask Ml including a light transmission portion M11 and a light blocking portion M12, the photoresist PR may be exposed to correspond to a position where the first electrode 210 described with reference to FIG. 3A is formed. In some embodiments, the area of a region where a photoresist pattern to be developed is disposed may be varied by varying a degree to which the photoresist PR is exposed to light.

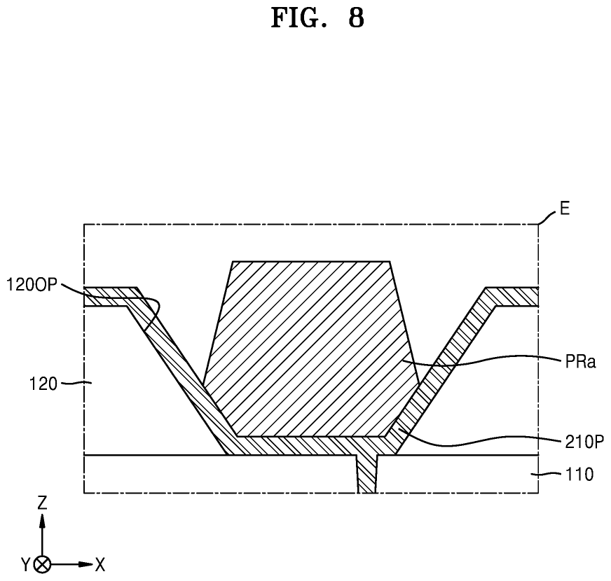

Referring to FIG. 8, a first photoresist pattern PRa may be formed on the preliminary first electrode 210P by developing the photoresist PR. The first photoresist pattern PRa may remain in an area of the photoresist PR that corresponds to the position where the first electrode 210 may be formed, and the remaining portion may be removed. The first photoresist pattern PRa may be disposed in the opening 120OP of the pixel-defining layer 120.

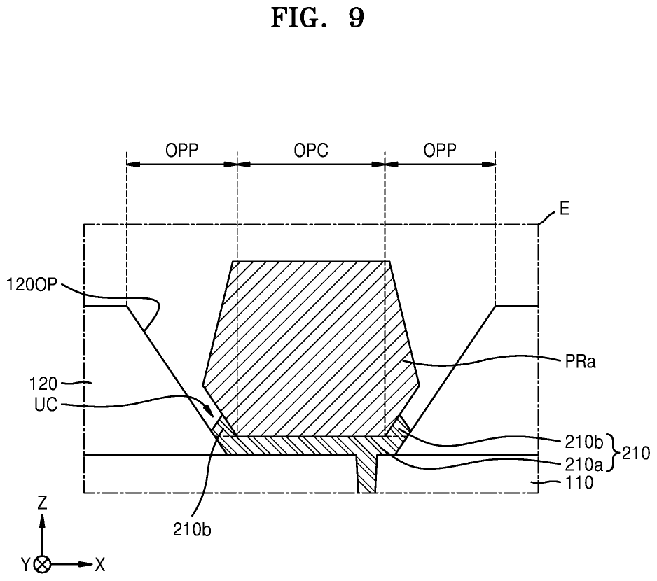

Referring to FIG. 9, the preliminary first electrode 210P may be etched by using the first photoresist pattern PRa as an etching mask, and thus, the first electrode 210 may be formed. An etching process for forming the first electrode 210 may be, for example, a wet etching process. Due to the etching process, a portion of the preliminary first electrode 210P may be removed in an area that does not overlap the first photoresist pattern PRa. In this regard, a portion of the preliminary first electrode 210P may be removed in an area overlapping an outer edge of the first photoresist pattern PRa, and thus, an undercut profile UC may be formed. Accordingly, the first electrode 210 including the first portion 210a disposed on an upper surface of the organic insulating layer 110 and the second portion 210b extending from the first portion 210a and disposed on a side wall of the pixel-defining layer 120 may be formed. A central portion of the first portion 210a of the first electrode 210 may be in the central area OPC of the opening 120OP of the pixel-defining layer 120, and the second portion 210b of the first electrode 210 may be in the peripheral area OPP of the opening 120OP of the pixel-defining layer 120. The second portion 210b may be a protrusion extending along the side wall of the pixel-defining layer 120 and protruding from the first portion 210a.

The first electrode 210 may be formed after formation of the pixel-defining layer 120 and accordingly may be disposed only in the opening 120OP of the pixel-defining layer 120. For example, an entire upper surface of the first electrode 210 may be exposed by the opening 120OP in the pixel-defining layer 120. The pixel-defining layer 120 may not cover the upper surface of the first electrode 210.

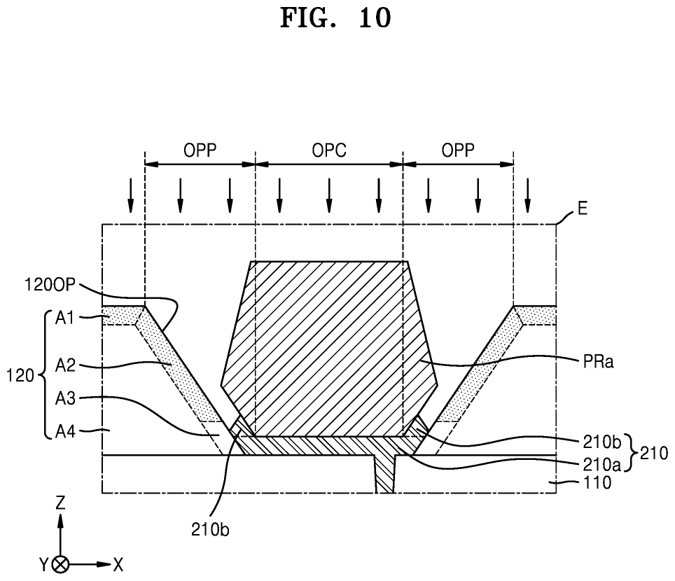

Referring to FIG. 10, a surface region of the pixel-defining layer 120 may be surface-treated to have liquid repellency by performing a surface treatment process. For example, a surface of the pixel-defining layer 120 may have liquid repellency due to a plasma surface treatment process. In this regard, the first electrode 210 may not be affected by the surface treatment process due to the first photoresist pattern PRa. Because the first photoresist pattern PRa may overlap the first electrode 210 and may cover the first electrode 210, the first electrode 210 may not be affected by the surface treatment process. Accordingly, unlike the surface of the pixel-defining layer 120, the first electrode 210 may maintain hydrophilic or lyophilic properties.

For example, the pixel-defining layer 120 may be surface-treated using fluoride-based plasma including CF₄ gas plasma or SF₆ gas plasma. For example, the pixel-defining layer 120 may include an organic material having a fluoro group (—F) or a fluorine compound. For example, an upper surface and side wall of the pixel-defining layer 120 may include an organic material having a fluoro group (—F). For example, a functional group of the upper surface and side wall of the pixel-defining layer 120 may be substituted with a fluoro group (—F).

The surface treatment process may be performed so that a portion of an upper surface and side surface of the pixel-defining layer 120 may have liquid repellency. An area that does not overlap the first photoresist pattern PRa and is exposed may be surface-treated to have liquid repellency. For example, the first area A1 adjacent to the upper surface of the pixel-defining layer 120 and the second area A2 adjacent to the side surface of the pixel-defining layer 120 and positioned above the first electrode 210 may have liquid repellency. For example, the first area A1 and the second area A2 of the pixel-defining layer 120 may be surface-treated, and thus, a functional group of the surface of the pixel-defining layer 120 may be substituted with a fluoro group (—F).

An area that overlaps the first photoresist pattern PRa and is not exposed to plasma gas may not be surface-treated. For example, the third area A3 adjacent to the side surface of the pixel-defining layer 120 and overlapping the first electrode 210 in the direction x or the direction y and the fourth area A4, which is the remaining area excluding the first to third areas A1 to A3, may not be surface-treated. Accordingly, in case that the surface treatment process is performed using fluoride-based plasma, a fluorine content of the pixel-defining layer 120 in the first area A1 and the second area A2 may be greater than a fluorine content of the pixel-defining layer 120 in the third area A3 and the fourth area A4.

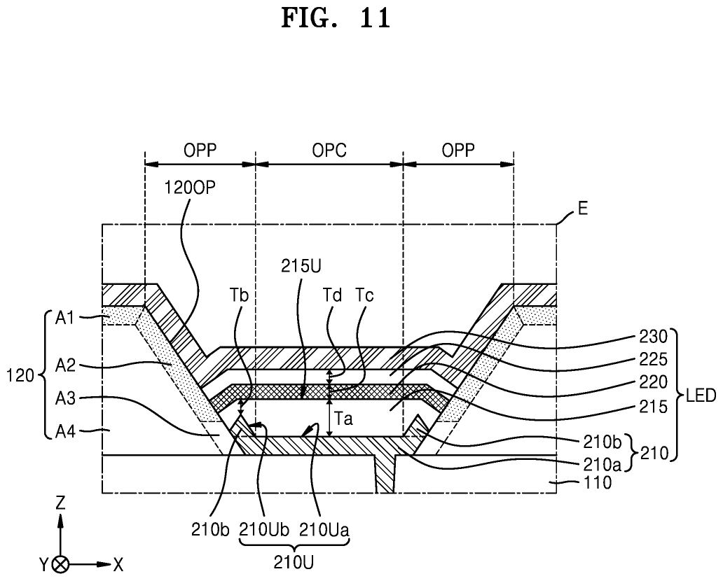

Referring to FIG. 11, the first photoresist pattern PRa may be removed. The first common layer 215, the emission layer 220, and the second common layer 225 may be sequentially formed on the first electrode 210. Each of the first common layer 215, the emission layer 220, and the second common layer 225 may be formed by performing, for example, an inkjet process. The first common layer 215, the emission layer 220, and the second common layer 225 may be formed in the opening 120OP of the pixel-defining layer 120. Each of the first common layer 215, the emission layer 220, and the second common layer 225 may be formed in an island pattern shape in the opening 120OP of the pixel-defining layer 120. In another embodiment, the first common layer 215 and the second common layer 225 may be formed to be entirely disposed over the substrate 100 to share light-emitting diodes LED.

The first common layer 215 is shown as a single layer, but is not limited thereto, and may have a single-layer or multi-layer structure. The first common layer 215 may be formed to include a hole transport layer (HTL) and/or a hole injection layer (HIL). The first common layer 215 may further include other functional layers in addition to the HTL and the HIL.

The upper surface 215U of the first common layer 215 may be formed to be at a higher level than the upper surface 210U of the first electrode 210. The upper surface 215U of the first common layer 215 may be formed to be at a higher level than the first upper surface portion 210Ua of the first electrode 210 and the second upper surface portion 210Ub of the first electrode 210. The upper surface 215U of the first common layer 215 may be at a higher level than the top of the first electrode 210. Because the upper surface 215U of the first common layer 215 may be higher than an uppermost end of the first electrode 210, a short circuit between the first electrode 210 and the second electrode 230 may be prevented.

Because the second area A2 of the pixel-defining layer 120 may have liquid repellency, the upper surface 215U of the first common layer 215 may be lower in height in an area adjacent to the side wall of the pixel-defining layer 120 than in the central area OPC of the opening 120OP of the pixel-defining layer 120. For example, the first common layer 215 may be formed to have an upper surface that is convex upwards at a central portion thereof. For example, at least a portion of the upper surface 215U of the first common layer 215 in the peripheral area OPP may be at a lower level than the upper surface 215U of the first common layer 215 in the central area OPC. The thickness Ta of the first common layer 215 in the central area OPC may be formed to be greater than the thickness Tb of the first common layer 215 in the peripheral area OPP.

The emission layer 220 may be, for example, an organic emission layer. The organic emission layer may include an organic material including a fluorescent or phosphorescent material that emits red, green, blue, or white light. The organic emission layer may be formed to include a low-molecular weight organic material or a polymer organic material.

Because the second area A2 of the pixel-defining layer 120 may have liquid repellency, an upper surface of the emission layer 220 may be lower in height in an area adjacent to the side wall of the pixel-defining layer 120 than in the central area OPC of the opening 120OP of the pixel-defining layer 120. For example, at least a portion of the upper surface of the emission layer 220 in the peripheral area OPP may be formed to be at a lower level than the upper surface of the emission layer 220 in the central area OPC.

The second common layer 225 is shown as a single layer, but is not limited thereto, and may have a single-layer or multi-layer structure. The second common layer 225 may be formed to include an electron transport layer (ETL) and/or an electron injection layer (EIL). The second common layer 225 may further include other functional layers in addition to the ETL and the EIL.

Because the second area A2 of the pixel-defining layer 120 may have liquid repellency, an upper surface of the second common layer 225 may be lower in height in an area adjacent to the side wall of the pixel-defining layer 120 than in the central area OPC of the opening 120OP of the pixel-defining layer 120. For example, the second common layer 225 may be formed to have an upper surface that is convex upwards at a central portion thereof. For example, at least a portion of the upper surface of the second common layer 225 in the peripheral area OPP may be formed to be at a lower level than the upper surface of the second common layer 225 in the central area OPC.

The thickness Ta of the first common layer 215 may be formed to be greater than the thickness Tc of the emission layer 220. The thickness Ta of the first common layer 215 may be formed to be greater than the thickness Td of the second common layer 225.

The second electrode 230 may be formed on the second common layer 225. The second electrode 230 may be formed to entirely cover the substrate 100 of the display area DA. The second electrode 230 may be a light-transmitting electrode or a reflective electrode. The second electrode 230 may include a conductive material having a low work function. For example, the second electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. As another example, the second electrode 230 may further include a layer, such as ITO, IZO, ZnO, or In₂O₃, on a (semi) transparent layer including the above material.

Referring to FIG. 3A again, the encapsulation layer 300 including at least one inorganic encapsulation layer and at least one organic encapsulation layer may be formed on the light-emitting diode LED.

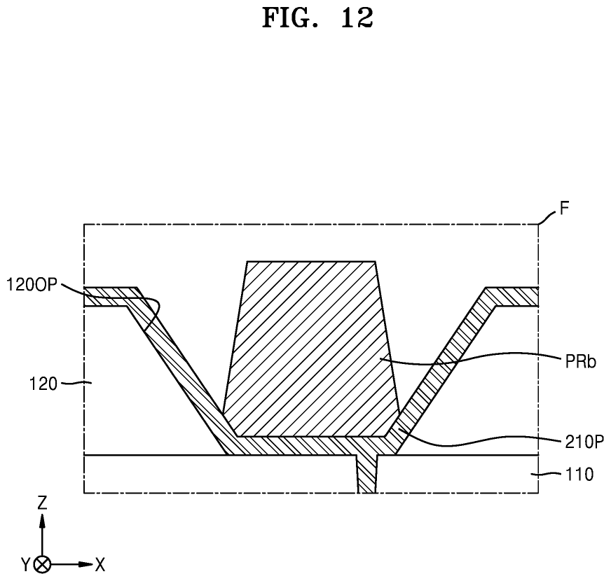

FIGS. 12 to 15 are schematic cross-sectional views of a method of manufacturing a display device, according to another embodiment. FIGS. 12 to 15 illustrate a manufacturing method for forming the embodiment described with reference to FIGS. 4A and 4B. FIGS. 12 to 15 illustrate a manufacturing method in the region corresponding to FIG. 4B.

FIGS. 12 to 15 illustrate the embodiment of a manufacturing method in which the area of a region for a photoresist pattern to be developed is reduced by relatively increasing an amount of exposure after forming the photoresist PR described with reference to FIG. 7. Accordingly, the previous manufacturing method described with reference to FIGS. 5 to 7 may be applied in the same way.

Referring to FIG. 12, a second photoresist pattern PRb may be formed by developing the photoresist PR (refer to FIG. 7). The second photoresist pattern PRb may remain in an area of the photoresist PR that corresponds to a position where the first electrode 210 is formed, and the remaining portion may be removed. In this regard, the second photoresist pattern PRb may be formed to be relatively small by relatively increasing an amount of exposure of the photoresist PR, and the second photoresist pattern PRb may be formed to be disposed in the opening 120OP of the pixel-defining layer 120.

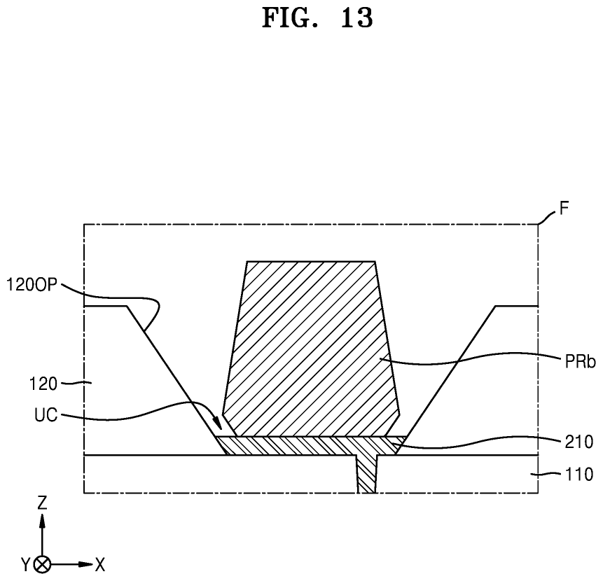

Referring to FIG. 13, the preliminary first electrode 210P may be etched by using the second photoresist pattern PRb as an etching mask, and thus, the first electrode 210 may be formed. An etching process for forming the first electrode 210 may be, for example, a wet etching process. For example, the preliminary first electrode 210P may be formed by etching using a wet etching process. Due to the etching process, a portion of the preliminary first electrode 210P may be removed in an area that does not overlap the second photoresist pattern PRb. In this regard, a portion of the preliminary first electrode 210P may be removed in an area overlapping an outer edge of the second photoresist pattern PRb, and thus, the undercut profile UC may be formed. In the embodiment, a degree to which the preliminary first electrode 210P is etched may be relatively large because an overlapping area between the second photoresist pattern PRb and the first electrode 210 may be relatively small. Accordingly, the first electrode 210 formed by etching the preliminary first electrode 210P may have a substantially flat upper surface. In another embodiment, the first electrode 210 may have a generally flat upper surface but may include a protrusion in an area adjacent to the pixel-defining layer 120.

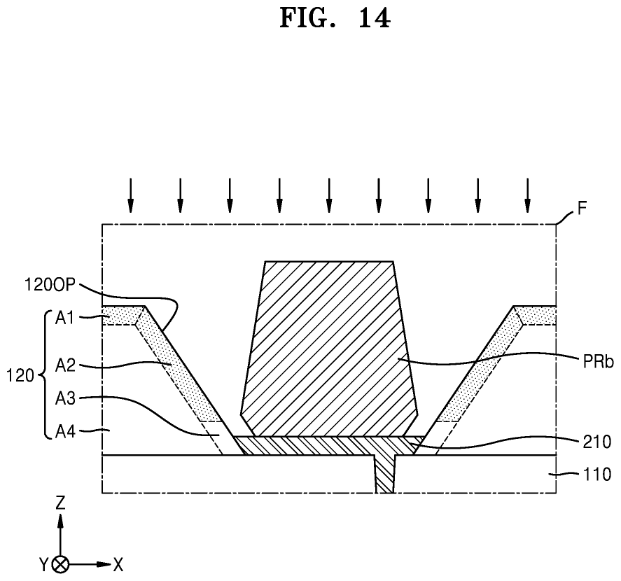

Referring to FIG. 14, a surface region of the pixel-defining layer 120 may be surface-treated to have liquid repellency by performing a surface treatment process. A description of the surface treatment process may be the same as that given with reference to FIG. 10, and thus, a redundant description thereof may be omitted.

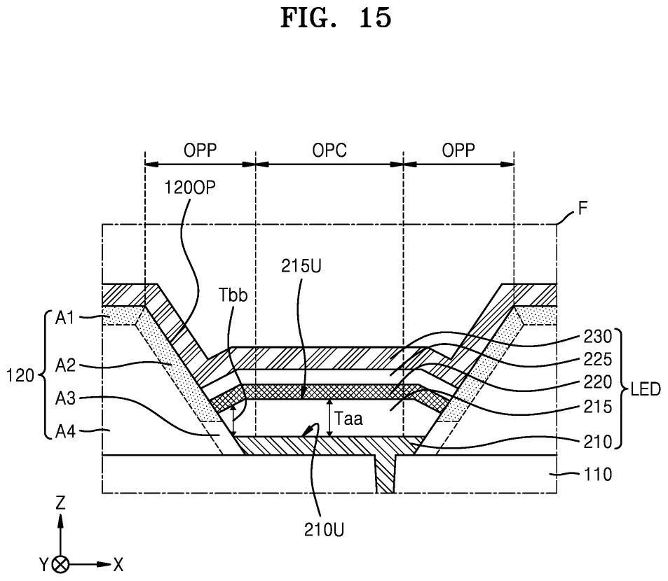

Referring to FIG. 15, the second photoresist pattern PRb may be removed, and the first common layer 215, the emission layer 220, the second common layer 225, and the second electrode 230 may be sequentially formed on the first electrode 210. A description of a method of forming the first common layer 215, the emission layer 220, the second common layer 225, and the second electrode 230 may be mostly the same as that given with reference to FIG. 11, and thus, a redundant description thereof may be omitted.

Even in case that an upper surface of the first electrode 210 is substantially flat, the upper surface 215U of the first common layer 215 may be lower in height in an area adjacent to the side wall of the pixel-defining layer 120 than in the central area OPC of the opening 120OP of the pixel-defining layer 120. For example, the first common layer 215 may be formed to have an upper surface that is convex upwards at a central portion thereof. For example, at least a portion of the upper surface 215U of the first common layer 215 in the peripheral area OPP may be at a lower level than the upper surface 215U of the first common layer 215 in the central area OPC. The thickness Taa of the first common layer 215 in the central area OPC may be formed to be greater than the thickness Tbb of the first common layer 215 in the peripheral area OPP.

Referring to FIG. 4A again, the encapsulation layer 300 including at least one of an inorganic encapsulation layer and an organic encapsulation layer may be formed on the light-emitting diode LED.

According to one or more of the above embodiments, a display device in which lighting quality is improved by forming a pixel electrode after forming a pixel-defining layer may be provided. However, one or more embodiments are not limited by such an effect.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a pixel circuit layer disposed on a substrate and comprising a pixel circuit;
a pixel-defining layer disposed on the pixel circuit layer and comprising an opening;
a first electrode disposed on the pixel circuit layer, disposed in the opening of the pixel-defining layer, and having a portion disposed on a side wall of the pixel-defining layer;
a first common layer on the first electrode;
an emission layer on the first common layer;
a second common layer on the emission layer; and
a second electrode on the second common layer,
wherein an upper surface of the first common layer is at a higher level than an upper surface of the first electrode.

2. The display device of claim 1, wherein
the first electrode comprises a first portion disposed on the pixel circuit layer and a second portion extending from the first portion and disposed on the side wall of the pixel-defining layer, and
the upper surface of the first common layer is at a higher level than a top of the second portion of the first electrode.

3. The display device of claim 1, wherein
the opening in the pixel-defining layer comprises a central area and a peripheral area outside the central area, and
the first common layer is thicker in the central area than in the peripheral area.

4. The display device of claim 1, wherein the first common layer has an upper surface that is convex upwards at a central portion of the upper surface.

5. The display device of claim 1, wherein
the opening in the pixel-defining layer comprises a central area and a peripheral area outside the central area, and
in the central area, the first common layer is thicker than the emission layer.

6. The display device of claim 1, wherein the first electrode is disposed only in the opening of the pixel-defining layer.

7. The display device of claim 1, wherein
the pixel-defining layer comprises a first area adjacent to an upper surface of the pixel-defining layer and a second area adjacent to the side wall of the pixel-defining layer, and
the pixel-defining layer has liquid repellency in the first area and the second area.

8. The display device of claim 7, wherein the pixel-defining layer comprises an organic material having a fluoro group (—F) in the first area and the second area.

9. The display device of claim 1, wherein
the first common layer comprises a hole injection layer, and
the second common layer comprises an electron transport layer.

10. A display device comprising:
a pixel circuit layer disposed on a substrate and comprising a pixel circuit;
a pixel-defining layer disposed on the pixel circuit layer and comprising an opening;
a first electrode disposed on the pixel circuit layer and disposed in the opening of the pixel-defining layer;
a first common layer disposed on the first electrode;
an emission layer disposed on the first common layer;
a second common layer disposed on the emission layer; and
a second electrode disposed on the second common layer, wherein
the pixel-defining layer comprises a first area adjacent to an upper surface of the pixel-defining layer and a second area adjacent to a side wall of the pixel-defining layer, and
the pixel-defining layer has liquid repellency in the first area and the second area.

11. The display device of claim 10, wherein
the second area of the pixel-defining layer is above the first electrode,
the pixel-defining layer further comprises a third area adjacent to the side wall of the pixel-defining layer and below the second area and a fourth area in addition to the first to third areas, and
a fluorine content of the pixel-defining layer in the first area or the second area is greater than a fluorine content of the pixel-defining layer in the third area or the fourth area.

12. The display device of claim 10, wherein an upper surface of the first common layer is at a higher level than an upper surface of the first electrode.

13. The display device of claim 10, wherein
the opening in the pixel-defining layer comprises a central area and a peripheral area outside the central area, and
the first common layer is thicker in the central area than in the peripheral area.

14. The display device of claim 10, wherein
the first electrode comprises a first portion disposed on the pixel circuit layer and a second portion extending from the first portion and disposed on the side wall of the pixel-defining layer, and
an upper surface of the first common layer is at a higher level than a top of the second portion of the first electrode.

15. The display device of claim 10, wherein the first electrode has a flat upper surface.

16. The display device of claim 10, wherein the first common layer is thicker than the emission layer.

17. The display device of claim 10, wherein the first common layer is thicker than the second common layer.

18. The display device of claim 10, wherein, in the first area and the second area of the pixel-defining layer, the pixel-defining layer comprises an organic material having a fluoro group (—F).

19. A method of manufacturing a display device, the method comprising:
forming a pixel circuit layer on a substrate;
forming a pixel-defining layer on the pixel circuit layer, the pixel-defining layer comprising an opening;
forming a preliminary first electrode on the pixel circuit layer and the pixel-defining layer;
forming a photoresist pattern on the preliminary first electrode;
etching the preliminary first electrode by using the photoresist pattern as an etching mask;
performing a surface treatment process on the pixel-defining layer such that a surface region of the pixel-defining layer has liquid repellency;
removing the photoresist pattern;
forming a first common layer, an emission layer, and a second common layer in the opening of the pixel-defining layer; and
forming a second electrode on the second common layer.

20. The method of claim 19, wherein the performing of the surface treatment process comprises using fluoride-based plasma.

21. The method of claim 19, wherein the preliminary first electrode is etched by a wet etching process.

22. The method of claim 19, wherein the emission layer is formed by an inkjet printing process.
